(19) United States
(12) Patent Application Publication
(10) Pub. No.: US 2024/0234571 A1
(43) Pub. Date: Jul. 11, 2024

(54) FIELD-EFFECT TRANSISTOR, AND METHOD OF PRODUCTION

(71) Applicant: Robert Bosch GmbH, Stuttgart (DE)

(72) Inventors: Jens Baringhaus, Sindelfingen (DE); Klaus Heyers, Reutlingen (DE)

(21) Appl. No.: 18/403,080

(22) Filed: Jan. 3, 2024

(30) Foreign Application Priority Data
Jan. 10, 2023 (DE) 10 2023 200 116.0

(51) Int. Cl. H01L 29/78; H01L 29/16; H01L 29/20; H01L 29/24; H01L 29/423; H01L 29/66

(52) U.S. Cl. CPC H01L 29/7827; H01L 29/1608; H01L 29/2003; H01L 29/24; H01L 29/4236; H01L 29/66068; H01L 29/66522; H01L 29/66666; H01L 29/66969

(57) ABSTRACT

A field-effect transistor. The field-effect transistor includes: a source layer doped according to a first type, a drain layer doped according to the first type, a channel layer located vertically between the source layer doped according to the first type and the drain layer doped according to the first type, and a plurality of gate trenches, which extend in the vertical direction from the source layer doped according to the first type to the drain layer doped according to the first type, wherein a fin is formed between each two gate trenches, wherein side surfaces of the fin face the gate trenches, wherein the channel layer is formed in at least a portion of the fin, and wherein an additional layer doped according to a second type is applied at least to one of the side surfaces of the fin.

### FIELD

The present invention relates to a field-effect transistor, in particular to a so-called trench MOSFET, and to a method for producing such a field-effect transistor.

### BACKGROUND INFORMATION

Field-effect transistors, in particular so-called MOSFETs, are used in various fields. A variant of this are so-called trench MOSFETs or T-MOSFETs, in which one channel is vertical. In this case, for example, an n-doped source layer and a channel layer located between this source layer and one of the n-doped drift layers are interrupted by trenches; gate electrodes are then arranged in such trenches.

### SUMMARY

According to the present invention, a field-effect transistor and a method for producing a field-effect transistor are provided. Advantageous embodiments of the present invention are disclosed herein.

The present invention relates to field-effect transistors, in particular with trenches, and their production. Different types of doping, specifically n-doping and p-doping, are used with semiconductor materials, wherein different components can be doped differently. For the sake of clarity, field-effect transistors are to be described below with a specific type of doping; n-doping is intended to be a doping of a first type, p-doping is intended to be a doping of a second type. However, it is understood that n-doping and p-doping can also be interchanged; i.e., the n-doping could be the second type of doping and the p-doping could be the first type of doping.

A field-effect transistor typically has an n-doped source layer and an n-doped drain layer (in particular comprising an n-doped drift layer, for example, applied as a so-called epitaxy layer or epitaxial layer). It also has a channel layer located vertically between the n-doped source layer and the n-doped drain layer. Furthermore, such a field-effect transistor has a plurality of gate trenches, which extend in the vertical direction from the n-doped source layer to the n-doped drain layer.

Furthermore, the field-effect transistor can have gate electrodes arranged in the gate trench, which are at least partially surrounded by a dielectric (for example, a so-called gate oxide), in particular in such a way that the gate electrode is insulated from the n-doped source layer, the channel layer and the n-doped drain layer. The gate electrode can be designed as one piece or can also be divided into at least two parts, specifically in such a way that a region of a bottom of the gate trench remains free. For example, a p-doped shielding region can be formed vertically below the gate trench, and thus in the n-doped drain layer.

A projection, a so-called fin, is formed or present between each two gate trenches. This is also referred to as a FinFET or a FinMOSFET.

It should be mentioned that such a field-effect transistor typically has a large number of such gate trenches and gate electrodes, and then also fins, for which the same applies as explained above, and is to be explained further. It is understood that, in addition to the gate electrodes, such a field-effect transistor also has source and drain connections, which can be formed in the conventional manner. This is a particular advantage of a trench MOSFET, since the vertical arrangement means that many gate electrodes can be arranged next to one another. In particular, the field-effect transistor can be designed as a SiC or GaN field-effect transistor; i.e., a substrate and/or generally used semiconductor material can be silicon carbide (SiC) or gallium nitride (GaN). However, semiconductor materials having an ultra-wide band gap, for example gallium oxide, can also be considered.

By selecting the appropriate geometry, epitaxial layer and implanted or used dopings, a switch-on resistance, threshold voltage, short-circuit resistance, oxide load and breakdown voltage in such a field-effect transistor can be optimized.

Such a field-effect transistor can be used alone or together with others, for example as a power switch. Preferred fields of application are, for example, in an electric drive train of a vehicle, for example in a current transformer (DC/DC converter, inverter), in charging devices for electrically powered vehicles or in solar inverters.

A FinFET or FinMOSFET is based on the depletion of the narrow, typically n-doped, fins (semiconductor fins). As a rule, the width of the fins in this case must be selected to be narrow enough that the entire fin can be depleted by the overlapping depletion zones that form on the side walls or side surfaces of the fins at the MOS interface, and thus forms a switchable channel region. Since the production of such narrow fins represents a process engineering challenge, one or both side surfaces or regions of the fin adjacent thereto can, for example, be provided with a p-doping (or, in general, doping according to the second type). As a result, the formation of the channel region in this portion of the fin is prevented, and the electrically active fin width becomes effectively narrower. This means that depletion can be achieved in a fin that is actually too wide structurally.

In this case, however, high structural precision is generally required for defining p-doped regions within the fin. However, typical methods such as ion implantation have an excessive inaccuracy in structural definition due to scattering processes.

According to an example embodiment of the present invention, it has been found that this problem can be remedied by applying an additional layer doped according to the second type, at least on one of the side surfaces of the fin. This can preferably be the case at two (or both) side surfaces of the fin, which side surfaces face different gate trenches. Such an additional layer extends in particular in the vertical direction up to the source layer doped according to the first type and is adjacent thereto.

According to an example embodiment of the present invention, instead of a partial doping of the fin, an additional p-doping (or, in general, conductive according to the second type) and thus depleting layer (the additional layer) is thus applied, e.g., deposited, onto one or both side walls of the fin. In this case, the additional layer is thus no longer within but outside the fin. The method of deposition instead of implantation allows, for example, the structural transition from p-doping to n-doping (in the fin), or vice versa, to be structurally sharp. The additional layer can achieve that a complete depletion in a smaller (i.e., structurally narrower) region is possible within the fin since the depletion zone, which is formed by a pn transition, has a greater width than a corresponding depletion zone of a semiconductor/insulator transition without additional p-doping.

The additional layer can be doped in order to be conductive according to the second type; intrinsically conductive materials are however also possible. In particular in the case of a p-doped or hole-conducting layer, the additional layer can be designed to be intrinsically hole-conducting (e.g., CuO or NiO) and can, for example, be applied by PVD (physical vapor deposition) (without temperature input).

A p-doped 4H-SiC layer, which is, for example, grown epitaxially, or a p-doped 3C-SiC layer, which is, for example, grown at lower temperatures than a comparable 4H-SiC layer, also comes into consideration, which can be advantageous for the structural integrity of the fin structure.

In one exemplary embodiment of the present invention, the fin is doped according to the second type in a region adjacent to the additional layer. This can, for example, be achieved by diffusing the doping of the additional layer or the hole conduction thereof (in the case of a p-doped additional layer) into the fin.

As mentioned, a field-effect transistor then in particular also has gate electrodes, which are introduced into the gate trenches. These gate electrodes are then in particular adjacent to the mentioned additional layers, at least where an additional layer is present.

In addition to the field-effect transistor, the present invention also relates to a method for the production thereof. A starting material is first provided for this purpose. This starting material comprises a source layer doped according to the first type, a drain layer doped according to the first type, a channel layer located vertically between the source layer doped according to the first type and the drain layer doped according to the first type, and a plurality of gate trenches, which extend in the vertical direction from the source layer doped according to the first type to the drain layer doped according to the first type. It is understood that (in the starting material and before the end of the production) the channel layer is the layer that is to later serve as a channel layer. A fin is formed between each two gate trenches, wherein side surfaces of the fin face the gate trenches, and wherein the channel layer has been or is formed in at least a portion of the fin.

In order to be able to obtain the starting material, further preceding steps can also be provided, in which, for example, the mentioned layers are generated, for example by suitable doping or implantation. Likewise, the fins or gate trenches can be generated in a conventional manner, e.g., by etching, optionally by means of a mask.

In a next step, the additional layer, which is conductive according to the second type, is then applied, for example by depositing the corresponding material. In this case, it is, for example, possible to first apply (deposit) the material for the additional layer onto a surface of the starting material; regions of the material can thereafter be removed again so that the material remains at least on the one of the side surfaces of the fins. This can, for example, be done by etching, optionally with a mask.

In one exemplary embodiment of the present invention, the doping according to the second type can also be generated in the fin in a region that is adjacent to the additional layer, e.g., by warming or heating (in particular at high temperature) so that the doping or the hole conduction diffuses into the fin.

In the further course, the gate electrodes can be inserted into the gate trenches. At least one, but also all gate electrodes, can be divided into at least two parts in such a way that a region of a bottom of the relevant gate trench remains free during insertion. Thereafter, the field-effect transistor can be metallized.

It is understood that further steps may be necessary for the final field-effect transistor, such as edge finishing and contact path implementation and the like; conventional methods can be used in this case. However, the steps described above relate in particular to the so-called cell field of the field-effect transistor, in which the gate trenches are formed.

Further advantages and embodiments of the present invention can be found in the description and the figures.

The present invention is shown schematically in the figures on the basis of exemplary embodiments and is described below with reference to the figures.

### BRIEF DESCRIPTION OF THE DRAWINGS

FIG. 1 schematically shows a field-effect transistor according to the present invention in a preferred embodiment.

FIG. 2 schematically shows a field-effect transistor according to the present invention in a further preferred embodiment.

FIG. 3 schematically shows a field-effect transistor according to the present invention in a further preferred embodiment.

FIG. 4 schematically shows a sequence of a method according to the present invention in a preferred embodiment.

### DETAILED DESCRIPTION OF EXAMPLE EMBODIMENTS

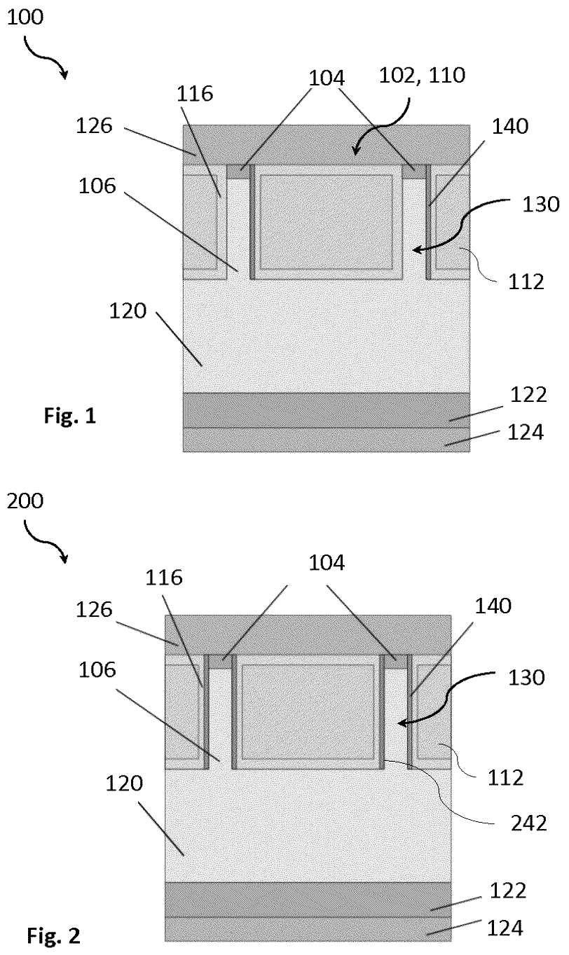

FIG. 1 schematically and by way of example shows a field-effect transistor 100 according to the present invention in a preferred embodiment, namely a so-called trench MOSFET as a so-called FinMOSFET. In particular, silicon carbide (SiC), gallium nitride (GaN) or gallium oxide can be used as the semiconductor material; these semiconductor materials have a wide to very wide band gap.

The field-effect transistor 100 has an n-doped source layer 104, an n-doped drain layer 120, optionally comprising or as an n-doped drift layer or so-called epitaxy layer 120, and a channel layer 106 located vertically (seen here top down) between the n-doped source layer 104 and the n-doped drain layer.

Furthermore, the field-effect transistor 100 has a plurality of gate electrodes 110 which are inserted into one of a plurality of gate trenches 102 in each case. The gate electrodes 110 each have a dielectric or a gate oxide 116, which surrounds a gate semiconductor material 112. The gate electrodes are used to control a channel region in the channel layer 106. In each case, a channel is formed in a region of the channel layer 106 that is adjacent to the gate trench or a gate electrode. The gate electrodes are typically guided within the gate trenches to the end of the trenches (i.e., the end of the cell field) and are guided out of the trenches at this location and contacted, or are contacted directly at this location.

Between each two of the gate trenches, and therefore also between each two of the gate electrodes, there is a projection or a so-called fin 130 in each case. In each case, the channel layer 106 is formed in the fins 130.

Furthermore, the field-effect transistor 100 has an n-doped substrate 122 adjacent to the bottom of the n-doped drift layer 120 and a drain material 124, such as a metal, adjacent to the bottom of the n-doped substrate 122. During the production, the n-doped drift layer 120 can, for example, be grown onto the substrate 122. In this case, the substrate 122 can be higher n-doped (e.g., more than 5e17 cm⁻³) than the n-doped drain or drift layer (e.g., less than 1e17 cm⁻³). In addition, the field-effect transistor 100 has a source electrode 126, which is adjacent to the n-doped source layer 104 at the top and is, for example, applied thereto.

Furthermore, on one side surface of each fin 130, here the side surface shown on the right, the field-effect transistor 100 has an additional layer 140, which is applied there. The additional layer 140 is, for example, doped according to the second type or p-doped and ensures that a channel region in the channel layer 106 reaches a desired width.

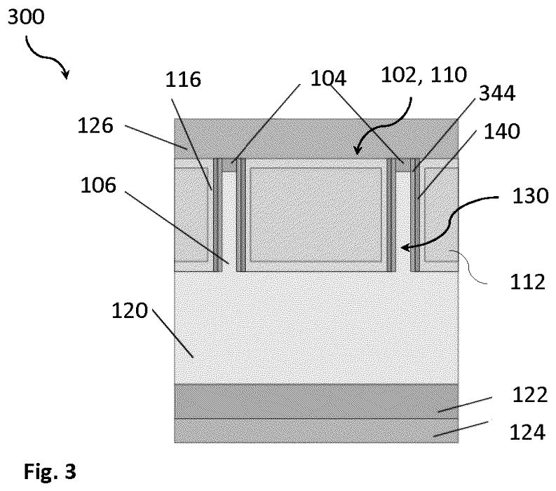

FIG. 2 schematically and by way of example shows a field-effect transistor 200 according to the present invention in a further preferred embodiment. The difference from the field-effect transistor 100 according to FIG. 1 is in particular that, on two side surfaces of each fin 130, the field-effect transistor 200 has an additional layer, which is applied there. In addition to the additional layer 140 already shown in FIG. 1, this is the additional layer 242, here on the side surface shown on the left. The additional layer 242 is also, for example, doped according to the second type or p-doped and ensures that a channel region in the channel layer 106 reaches a desired width.

Regarding the further components, reference is made to FIG. 1 and the associated description, which applies equally here.

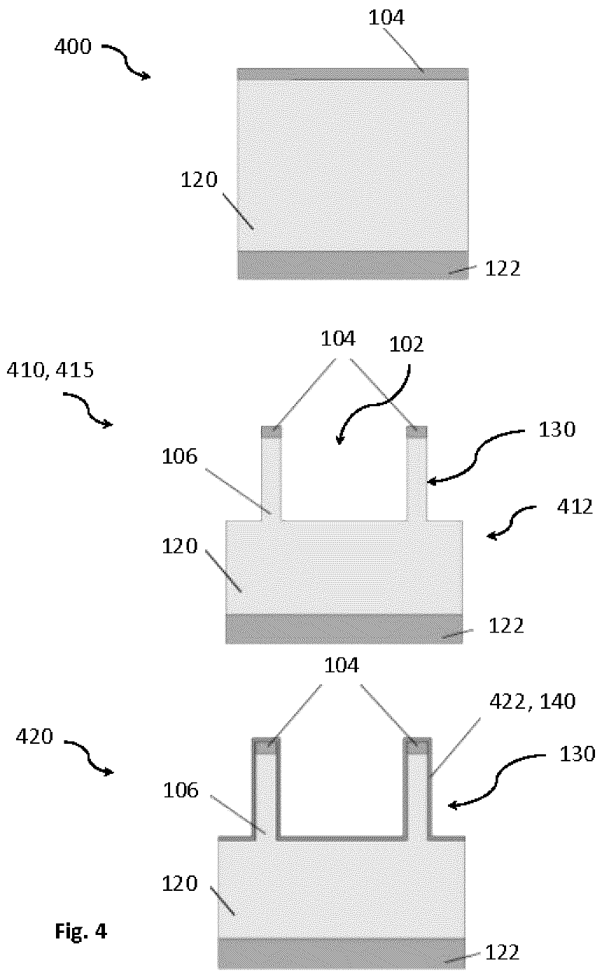

FIG. 3 schematically and by way of example shows a field-effect transistor 300 according to the present invention in a further preferred embodiment. The difference from the field-effect transistor 200 according to FIG. 2 is in particular that, in regions 344 of the fins 130, which region is in each case adjacent to the relevant additional layer, the field-effect transistor 200 is doped according to the second type or p-doped. As mentioned, this can take place by warming so that, for example, the doping of the additional layer diffuses into the fin.

It is thus also achieved that the channel region in the channel layer 106 reaches a desired width. For example, a less thick additional layer than in the examples of FIGS. 1 and 2 can thus be selected since the diffusion expands the region that is doped according to the second type or p-doped. It is understood that, for example, such a region is also formed only on one side surface of the fins. Likewise, for example in the case of only one additional layer per fin (cf. FIG. 2), such a region can then be formed there.

Regarding the further components, reference is made to FIGS. 1 and 2 and the associated description, which applies equally here.

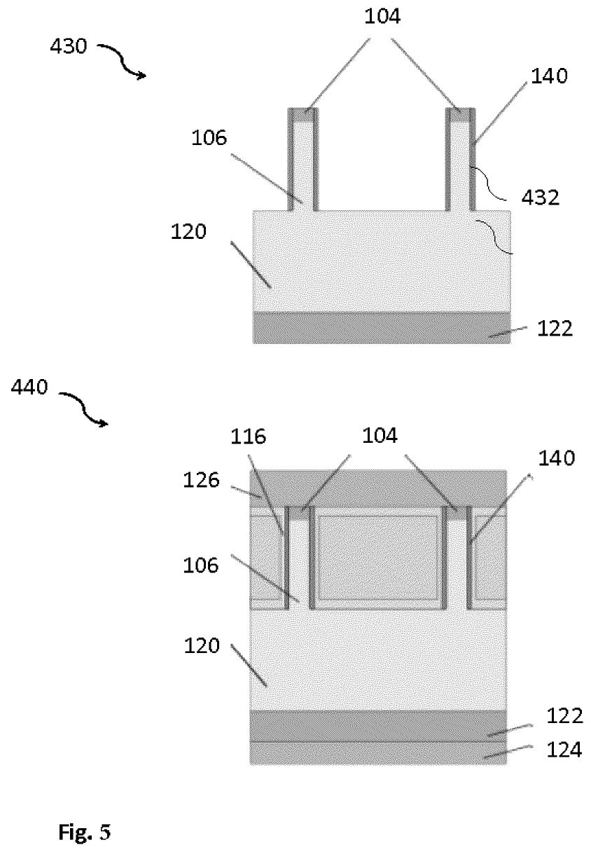

FIG. 4 schematically and by way of example shows a sequence of a method according to the present invention in a preferred embodiment. In each case, illustrations are shown for various, but not all, steps. In particular, a field-effect transistor, such as one of the field-effect transistors shown in FIGS. 1 to 3, can be produced.

In a step 400, the drain layer 120, in particular as a drift layer, is, for example, first grown epitaxially onto a substrate 122 (e.g., highly n-doped wafer). An n-doped source layer 104 can in turn be applied to the drain layer 120.

In a step 410, the fins 130 can then be structured, optionally using a suitable mask, i.e., the gate trenches 102 can be formed. This ultimately also results in the channel layer 106 (or a layer that later serves as such) in the fins 130.

The substrate thus processed can then be provided in step 415 as the starting material 412 for the further steps.

In a step 420, a material 422 is applied or deposited onto a surface of the starting material 412. In this case, the entire surface, including the bottoms of the gate trenches and side surfaces or side walls of the fins 130 and also the upper side thereof, can be covered.

In a step 430, the material 422 is then removed again to such an extent that only the desired additional layers 140 remain, i.e., for example, in each case, on only one side surface of the fins or also on both. A suitable mask can, for example, be used for this purpose.

Optionally, a further step can be performed, in which a doping according to the second type is formed in the fin 130 in a region that is adjacent to the additional layer doped according to the second type, for example by diffusion of the doping of the additional layer.

Further steps can follow in order to finish the field-effect transistor, such as inserting the gate electrodes, forming contacts and metalization, for example as the application of drain and source material as shown in FIG. 1, 2, or 3. This is denoted here by 300 by way of example.

1-12. (canceled)

13. A field-effect transistor, comprising:
a source layer doped according to a first type;
a drain layer doped according to the first type;
a channel layer located vertically between the source layer doped according to the first type and the drain layer doped according to the first type;
a plurality of gate trenches, which extend in a vertical direction from the source layer doped according to the first type to the drain layer doped according to the first type;
a fin formed between each two of the gate trenches, wherein side surfaces of the fin face the gate trenches;
wherein the channel layer is formed in at least a portion of the fin; and
wherein an additional layer, which is conductive according to a second type, is applied at least to one of the side surfaces of the fin.

14. The field-effect transistor according to claim 13, wherein the additional layer extends in the vertical direction up to the source layer doped according to the first type and is adjacent to the source layer doped according to the first type.

15. The field-effect transistor according to claim 13, wherein the fin is doped according to the second type in a region that is adjacent to the additional layer.

16. The field-effect transistor according to claim 13, wherein an additional layer is applied to each of two side surfaces of the fin that face different gate trenches.

17. The field-effect transistor according to claim 13, further comprising a gate electrode arranged in one of the gate trenches, wherein the gate electrode is adjacent to the additional layer.

18. The field-effect transistor according to claim 13, wherein the additional layer is formed as one of the following:
intrinsically hole-conducting,
p-doped 4H-SiC layer,
p-doped 3C-SiC layer.

19. The field-effect transistor according to claim 13, wherein the field-effect transitory is an SiC field-effect transistor, or a GaN field-effect transistor, or a gallium-oxide field-effect transistor.

20. A method for producing a field-effect transistor, comprising the following steps:
providing a starting material, wherein the starting material includes a source layer doped according to a first type, a drain layer doped according to the first type, a channel layer located vertically between the source layer doped according to the first type and the drain layer doped according to the first type, and a plurality of gate trenches, which extend in the vertical direction from the source layer doped according to the first type to the drain layer doped according to the first type;
forming a fin between each two of the gate trenches, wherein side surfaces of the fin face the gate trenches, and wherein the channel layer has been or is formed in at least a portion of the fin; and
applying an additional layer, which is conductive according to a second type, at least to one of the side surfaces of the fin.

21. The method according to claim 20, wherein the application of the additional layer includes:
applying material for the additional layer to a surface of the starting material; and
removing material applied to the surface in such a way that the additional layer remains at least on the one of the side surfaces of the fin.

22. The method according to claim 20, further comprising:
forming a doping according to the second type in the fin in a region that is adjacent to the doped additional layer.

23. The method according to claim 22, wherein the doping according to the second type is formed in the fin in a region that is adjacent to the additional layer, in such a way that the conductivity according to the second type of the additional layer is diffused into the region of the fin by warming.

24. The method according to claim 20, wherein material for the doped additional layer is applied to the surface of the starting material by depositing the material.
